(19) United States
(12) Patent Application Publication
(10) Pub. No.: US 2025/0287726 A1
(43) Pub. Date: Sep. 11, 2025

(54) SILICON WAFER TEXTURING METHOD, TEXTURED SILICON WAFER, CRYSTALLINE SILICON CELL AND MANUFACTURING METHOD THEREFOR

(71) Applicant: HENGDIAN GROUP DMEGC MAGNETICS CO., LTD., Jinhua (CN)

(72) Inventors: Chaoyan FANG, Jinhua (CN); Qingshan DU, Jinhua (CN); Hongjie PENG, Jinhua (CN); Wenrui WANG, Jinhua (CN); Yong REN, Jinhua (CN); Yue HE, Jinhua (CN)

(21) Appl. No.: 19/218,664

(22) Filed: May 27, 2025

Related U.S. Application Data
(63) Continuation of application No. PCT/CN2023/127140, filed on Oct. 27, 2023.

(30) Foreign Application Priority Data
Aug. 4, 2023 (CN) 202310980080.0

(51) Int. Cl. H10F 77/70; H01L 21/306

(52) U.S. Cl. CPC H10F 77/703; H01L 21/30604

(57) ABSTRACT

A silicon wafer texturing method and a textured silicon wafer. The texturing method includes: forming a pyramid textured surface on a silicon wafer; then carrying out a rounding treatment on the pyramid textured surface to form a rounded pyramid-shaped structure; and then forming pits on the rounded textured surface to finish the texturing, wherein the rounding treatment includes: successively performing a first treatment and a second treatment in a first mixed solution and a second mixed solution, the first mixed solution including HNO₃ and HF, a mass fraction of HNO₃ being greater than a mass fraction of HF, the second mixed solution including HNO₃ and HF, and a mass fraction of HNO₃ being less than a mass fraction of HF. For the obtained pits, a density of the pits is 10/cm² to 100/cm², a width is 0.01 μm to 0.08 μm, and a depth is 5 nm to 50 nm.

### CROSS to REFERENCE TO RELATED APPLICATIONS

This application is a continuation of international patent application No. PCT/CN2023/127140, filed on Oct. 27, 2023, which claims priority to Chinese patent application No. 202310980080.0, filed on Aug. 4, 2023, and titled “SILICON WAFER TEXTURING METHOD, TEXTURED SILICON WAFER, CRYSTALLINE SILICON CELL AND MANUFACTURING METHOD THEREFOR”, the contents of which are hereby incorporated by reference in its entirety.

### TECHNICAL FIELD

The present disclosure relates to the field of solar cell, in particular, to a silicon wafer texturing method, a textured silicon wafer, a crystalline silicon cell and a manufacturing method therefor.

### BACKGROUND

A texturing process is a process of forming pyramid-shaped structures on a surface of silicon wafers, so as to reduce reflectivity of the silicon wafers. Currently, textured surfaces formed by the texturing process in the related art generally have pyramid tips that are relatively sharp. For the textured surfaces prepared by the methods in the related art, passivation film depositions on the pyramid tips and pyramid bases tends to differ from those on other areas, with poorer deposition quality in these regions. As a result, the pyramid tips and pyramid bases exhibit higher recombination rates and defect state densities, which negatively impact the quality of solar cells. Therefore, it is necessary to optimize the textured surface to improve the deposition quality of passivation film and enhance passivation performance.

In related art, the method for optimizing the textured surface mainly involves treating the textured surface having pyramid-shapes structures with strong oxidative acidic solutions to process a rounding treatment. In the related art, the greater the degree of the rounding treatment, the better deposition quality of passivation film, and, consequently, the better the passivation performance, which leads to an increase in an open-circuit voltage of the fabricated solar cells. However, rounding the textured surface also correspondingly increases the reflectivity of the silicon wafers, thereby reducing the short-circuit current of the solar cells. Therefore, balancing improved passivation performance with low reflectivity of the silicon wafers has become a key factor limiting the high performance of solar cells.

### SUMMARY

A method for texturing a silicon wafer, a textured silicon wafer, a crystalline silicon cell and a method for preparing the crystalline silicon cell are provided in the present disclosure.

A method for texturing a silicon wafer, which includes following steps: forming a textured surface on a silicon wafer, wherein a pyramid-shaped structure is formed on the textured surface; subjecting a rounding treatment on the textured surface to form a rounded pyramid-shaped structure and obtaining a rounded textured surface, wherein the rounding treatment includes: a first treatment of first placing the silicon wafer having the textured surface in a first mixed solution; a second treatment of then placing silicon wafer having the textured surface in a second mixed solution; and at least repeating the first treatment and the second treatment twice, wherein the first mixed solution includes HNO₃ and HF, a mass fraction of HNO₃ in the first mixed solution is greater than a mass fraction of HF in the first mixed solution, the second mixed solution includes HNO₃ and HF, and a mass fraction of HNO₃ in the second mixed solution is less than a mass fraction of HF in the second mixed solution, and a time of the first treatment is longer than a time of the second treatment; and forming pits on the rounded textured surface to texture the silicon wafer, wherein a density of the pits on the rounded textured surface is in a range of 10/cm² to 100/cm², a width of one of the pits is in a range of 0.01 μm to 0.08 μm, and a depth of one of the pits is in a range of 5 nm to 50 nm.

In some embodiments, the first treatment and the second treatment repeats 5 times to 20 times.

In some embodiments, the time of the first treatment is in a range of 15 s to 20 s; and/or, the time of the second treatment is in a range of 5 s to 10 s.

In some embodiments, a concentration of HNO₃ in the first mixed solution is in a range of 40 wt % to 80 wt %, and a concentration of HF in the first mixed solution is in a range of 10 wt % to 20 wt %; and/or, a concentration of HNO₃ in the second mixed solution is in a range of 10 wt % to 20 wt %, and a concentration of HF in the second mixed solution is in a range of 40 wt % to 80 wt %.

In some embodiments, the step of forming pits on the rounded textured surface includes forming the pits on the rounded textured surface by method of metal etching.

In some embodiments, the method for texturing the silicon wafer further includes following steps: successively performing a third treatment with a third mixed solution and a fourth treatment with a fourth mixed solution the rounded pyramid-shaped structure, wherein the third mixed solution includes cupric ions and HF, a concentration of the cupric ions is in a range of 1 wt % to 5 wt %, a concentration of HF is in a range of 40 wt % to 60 wt %, and a time of the third treatment is in a range of 100 s to 200 s, the fourth mixed solution includes HCl and H₂O₂, a concentration of HCl is in a range of 2 wt % to 10 wt %, a concentration of H₂O₂ is in a range of 5 wt % to 20 wt %, and a time of the fourth treatment is in a range of 50 s to 200 s.

In some embodiments, a size of the pyramid-shaped structure is defined as a, and the size a of the pyramid-shaped structure is in a range of 1 μm to 2.5 μm.

A textured silicon wafer prepared by the method for texturing the silicon wafer described above.

A method for preparing a crystalline silicon cell, which includes the method for texturing the silicon wafer described above.

A crystalline silicon cell prepared by the method for preparing a crystalline silicon cell described above.

Details of one or more embodiments of the present application are presented in the following accompanying drawings and description in order to make other features, purposes and advantages of the present application more concise and understandable.

### BRIEF DESCRIPTION OF THE DRAWINGS

In order to better describe and illustrate the embodiments and/or examples of the present application disclosed herein, reference may be made to one or more of the accompanying drawings. The additional details or examples used to describe the accompanying drawings should not be considered a limitation on the scope of any of the disclosed applications, the embodiments and/or examples currently described, and the best mode of these applications as currently understood.

FIG. 1 is a schematic diagram of a textured surface of a silicon wafer after a texturing process in some embodiments of the present disclosure.

FIG. 2 is a schematic diagram of a rounded textured surface.

FIG. 3 is a schematic diagram showing a principle for performing a metal etching process to generate pits on the rounded textured surface.

FIG. 4 is a schematic diagram of a rounded textured surface having pits on the surface of the rounded textured surface.

In the figures, 1 represents a silicon wafer; 10 represents a textured surface; 11 represents a pyramid-shaped structure; 20 represents a rounded textured surface; 21 represents a pit; and 22 represents a rounded pyramid-shaped structure.

### DETAILED DESCRIPTION

In order to facilitate an understanding of the present disclosure, the present disclosure will be described in greater detail hereinafter. However, it should be understood that the present disclosure can be realized in many different forms and is not limited to the implementations or embodiments described herein. Rather, these implementations or embodiments are provided to enable a more thorough and comprehensive understanding of the disclosure of the present disclosure.

Unless otherwise defined, all technical and scientific terms used herein have the same meaning as commonly understood by those skilled in the art belonging to the present disclosure. Terms used herein in the specification of the present disclosure are used only for the purpose of describing specific implementations or embodiments and are not intended to limit the present disclosure. The term “and/or” optionally includes any one of two or more related listed items, as well as any and all combinations of related listed items, the any and all combinations including any two of the related listed items, any more of the related listed items, or a combination of all of the related listed items.

A method for texturing a silicon wafer, which includes following steps.
Step S1, forming a textured surface 10 on a silicon wafer 1, wherein a pyramid-shaped structure 11 is formed on the textured surface 10;
Step S2, subjecting a rounding treatment on the pyramid-shaped structure 11 to form a rounded pyramid-shaped structure 22, wherein the rounding treatment includes: a first treatment of first placing the silicon wafer 1 having the textured surface 10 in a first mixed solution; a second treatment of then placing silicon wafer 1 having the textured surface 10 in a second mixed solution; and at least repeating the first treatment and the second treatment twice, wherein the first mixed solution includes HNO₃ and HF, a mass fraction of HNO₃ in the first mixed solution is greater than a mass fraction of HF in the first mixed solution, the second mixed solution includes HNO₃ and HF, and a mass fraction of HNO₃ in the second mixed solution is less than a mass fraction of HF in the second mixed solution, and a time of the first treatment is longer than a time of the second treatment; and
Step S3, forming pits 21 on the rounded textured surface 20 to texture the silicon wafer, wherein a density of the pits 21 on the rounded textured surface 20 is in a range of 10/cm² to 100/cm², a width of one of the pits 21 is in a range of 0.01 μm to 0.08 μm, and a depth of one of the pits 21 is in a range of 5 nm to 50 nm.

In Step S1, steps for forming a textured surface 10 on a silicon wafer 1 are not limited. In some embodiments, the steps for forming a textured surface 10 on a silicon wafer 1 includes: precleaning a silicon wafer 1, and subjecting a texturing process on the silicon wafer 1 to obtain the textured surface 10.

In some embodiments, in the step of precleaning a silicon wafer 1, preparing a precleaning solution with NaOH and H₂O₂ to remove greasy dirt, shear marks and the like on the silicon wafer 1. During a process of precleaning the silicon wafer 1, a concentration of NaOH in the precleaning solution can be optionally in a range of 0.05 wt % to 0.2 wt %, a concentration of H₂O₂ in the precleaning solution can be optionally in a range of 1 wt % to 5 wt %, a time of the process of precleaning the silicon wafer 1 can be optionally in a range of 50 s to 150 s, and a temperature of the process of precleaning the silicon wafer 1 can be optionally in a range of 60° C. to 65° C. After the process of precleaning the silicon wafer 1, the silicon wafer 1 can be washed with deionized water, and the time of washing the silicon wafer 1 with deionized water is in a range of 50 s to 100 s.

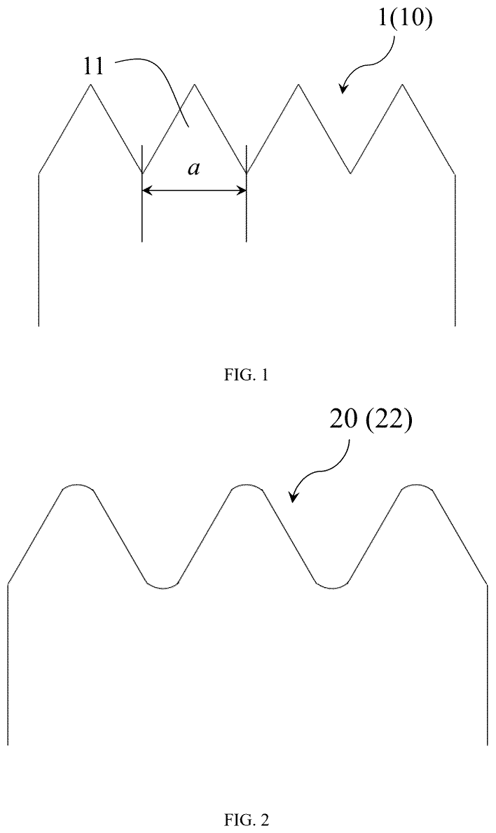

In the texturing process, an alkaline texturing solution can be prepared with NaOH and a texturing additive, and the textured surface 10 can be etched on the silicon wafer 1 in the alkaline texturing solution. Referring to FIG. 1, a size of the pyramid-shaped structure 11 is defined as a, and the size a of the pyramid-shaped structure 11 is in a range of 1 μm to 2.5 μm. Specifically, the a size a of the pyramid-shaped structure 11 on the textured surface 10 is a size of a diagonal of a base of the pyramid-shaped structure 11 on the textured surface 10. In this way, it is more convenient to form pits 21 on the rounded textured surface 20 after the rounding treatment.

In some embodiments, in the alkaline texturing solution, the concentration of NaOH can be optionally in a range of 0.5 wt % to 5 wt %, a concentration of the texturing additive can be optionally in a range of 0.3 wt % to 1 wt %, a time of texturing process can be optionally in a range of 200 s to 300 s, and a temperature of the texturing process can be optionally in a range of 65° C. to 75° C., so as to generate the pyramid-shaped structures having the size in the range described above. After the texturing process, the silicon wafer 1 can optionally be washed with deionized water, the time of washing the silicon wafer 1 with the deionized water can be in a range of 50 s to 100 s. A schematic diagram of the textured surface after the texturing process is shown in FIG. 1.

In the rounding treatment, HNO₃ can make a sharp-shaped area of the pyramid-shaped structures in the textured region oxide to generate silicon oxide, and HF can remove the silicon oxide obtained after the oxidation process. That is, HNO₃ and HF play different roles, HNO₃ plays a role of oxidation, and HF plays a role of removing the silicon oxide, so as to scapple the sharp-shaped area. If the silicon oxide generated by HNO₃ oxidation cannot be removed effectively in time, the silicon oxide will restrict reaction between HNO₃ and the silicon in the inner layer, which greatly affects the rounding treatment. Therefore, how to achieve a balance between the generation and removal of silicon oxide is the key to improving the rounding effect.

Therefore, in step S2 of the present disclosure, a first mixed solution including HNO₃ having a high concentration and HF having a low concentration can be firstly used to perform the first treatment, and a second mixed solution including HNO₃ having a low concentration and HF having a high concentration can be then used to perform the second treatment, which can be defined as one circulation. A plurality of circulation can be carried out to perform the rounding treatment of the textured surface, and a time distribution of the first treatment and the second treatment can be controlled at the same time, so that generation and removal of the silicon oxide can be balanced, so as to firmly and quickly round the whole textured surface. A schematic diagram of the pyramid textured surface after the rounding treatment is shown in FIG. 2.

In some embodiments, a concentration of HNO₃ in the first mixed solution can optionally be in a range of 40 wt % to 80 wt %, and a concentration of HF in the first mixed solution can optionally be in a range of 10 wt % to 20 wt %; and/or, a concentration of HNO₃ in the second mixed solution can optionally be in a range of 10 wt % to 20 wt %, and a concentration of HF in the second mixed solution can optionally be in a range of 40 wt % to 80 wt %. The time of the first treatment can optionally be in a range of 15 s to 20 s; and/or, the time of the second treatment can optionally be in a range of 5 s to 10 s. Thus, firmly and quickly rounding the whole textured surface can be further achieved in the rounding treatment. In other words, by subjecting the textured surface with first mixed solution having a certain percentage and the second mixed solution having a certain percentage to repeating of the first treatment and the second treatment, and controlling time distribution of the first treatment and the second treatment in each repeating, the whole textured surface can be firmly and quickly rounded.

In some embodiments, in each circulation of the plurality of circulations, the time of the first treatment can be the same or not, and the time of the second treatment can be the same or not. For example, in each circulation of the plurality of circulations, the time of the first treatment can be kept the same, and the time of the second treatment can be kept the same; optionally, in each circulation of the plurality of circulations, the time of the treatment and the time of the second treatment can gradually decrease with increase of the number of the circulations, so as to avoid increase of the reflectivity of the textured surface caused by excessive rounding treatment; and optionally, in each circulation of the plurality of circulations, the time of the first treatment and the time of the second treatment can gradually increase with increase of the number of the circulations.

In Step S3, when a density of the pits 21 on the rounded textured surface 20 is in a range of 10/cm² to 100/cm², a width of one of the pits 21 is in a range of 0.01 μm to 0.08 μm, and a depth of one of the pits 21 is in a range of 5 nm to 50 nm, not only does the deposition performance of the passivation film be unaffected, but a specific surface area of the textured surface is also increased, thereby allowing the reflectivity of the textured surface being kept below 5%. In this way, in the preparation of the crystalline silicon cell, a conversion efficiency of the crystalline silicon cell can be effectively improved when the method for texturing described above is applied.

In some embodiments, the density of the pits 21 on the rounded textured surface 20 is in a range of 40/cm² to 80/cm², which facilitates obtaining a textured surface having better reflectivity and better passivation performance, thereby effectively improving the conversion efficiency of the crystalline silicon cell.

In Step S3, the method for forming pits 21 on the rounded textured surface 20 will not be restricted. Optionally, the step of forming pits 21 on the rounded textured surface 20 includes forming the pits 21 on the rounded textured surface 20 by method of metal etching. The step the pits 21 on the rounded textured surface 20 by method of metal etching can include: successively performing a third treatment with a third mixed solution and a fourth treatment with a fourth mixed solution the rounded textured surface 20, wherein the third mixed solution includes cupric ions and HF, a concentration of the cupric ions is in a range of 1 wt % to 5 wt %, a concentration of HF is in a range of 40 wt % to 60 wt %, and a time of the third treatment is in a range of 100 s to 200 s, the fourth mixed solution includes HCl and H₂O₂, a concentration of HCl is in a range of 2 wt % to 10 wt %, a concentration of H₂O₂ is in a range of 5 wt % to 20 wt %, and a time of the fourth treatment is in a range of 50 s to 200 s. In the third mixed solution, the cupric ions can be sourced from at least one of copper chloride or cooper nitrate.

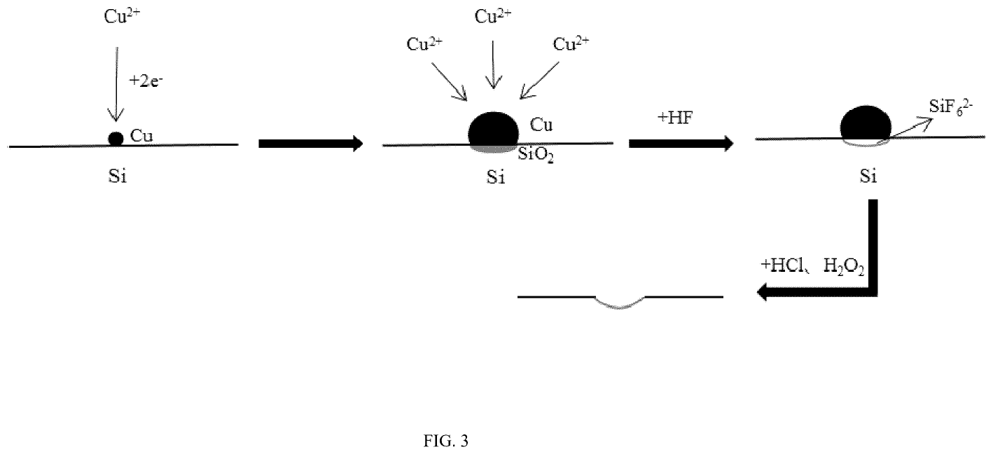

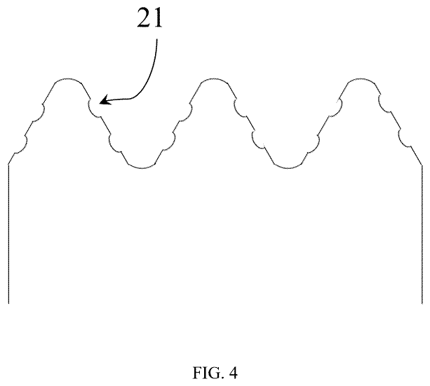

A principle for performing a metal etching process to generate pits 21 on the rounded textured surface 20 is mainly shown in FIG. 3. In the process of the third treatment, Cu²⁺ can react with Si to form copper particles at sites having relative high electroactivity on the surface of the rounded textured surface 20, so as to form copper cores. In addition, an electrode potential of Cu is higher than an electrode potential of Si. The Cu²⁺ in the solution may continually react with the Si on the rounded textured surface 20 and form the copper particles, and the Si may by oxidized to generate silicon oxide, thus the copper particles may accumulate and become greater, and relatively thick silicon oxide aggregations may be formed under the cooper particles. Then, the HF in the solution may react with the silicon oxide aggregation to generate SiF₆²⁻, and the pits 21 below may be generated after the silicon oxide aggregations are removed. Finally, the fourth mixed solution including HCl and H₂O₂ may be applied to perform the fourth treatment to remove the cooper particles accumulated above, so as to form pits 21 on the rounded textured surface 20. A schematic diagram of the rounded textured surface 20 having the pits 21 is shown in FIG. 4.

In the present disclosure, a textured silicon wafer prepared by the method for texturing the silicon wafer 1 described above is further provided.

In the present disclosure, a method for preparing a crystalline silicon cell is further provided. The method includes the method for texturing the silicon wafer 1 described above. Then the textured silicon wafer can be subjected to processing such as diffusion, washing, coating, printing and sintering to prepare the crystalline silicon cell.

In the present disclosure, a crystalline silicon cell prepared by the method for preparing a crystalline silicon cell described above is further provided. The crystalline silicon cell may be a TOPCon cell, a PERC cell and the like.

In the method for preparing the crystalline silicon cells, passivation performance of the silicon wafer 1 can be enhanced while maintaining low reflectivity of the silicon wafer 1 when the method for texturing the silicon wafer 1 in the present disclosure is applied. In addition, both an open-circuit voltage of the crystalline silicon cell and a short-circuit current of the crystalline silicon cell can be improved, thereby effectively improving the conversion efficiency of crystalline silicon cells.

The method for texturing the silicon wafer, the silicon wafer, the crystalline silicon cell and the method therefor will be further described in details in conjunction with the embodiments hereinafter.

### First Embodiment

A precleaning solution was prepared with NaOH and H₂O₂. A concentration of NaOH in the precleaning solution was 0.1 wt %, and a concentration of H₂O₂ in the precleaning solution was 3 wt %. A silicon wafer was treated in the precleaning solution at a temperature of 65° C. for 100 s, and then the silicon wafer was washed with deionized water for 80 s.

An alkaline texturing solution was prepared with NaOH and a texturing additive. In the alkaline texturing solution, a concentration of NaOH was 2 wt %, and a concentration of the texturing additive was 0.5 wt %. The precleaned silicon wafer was treated in the alkaline texturing solution at a temperature of 70° C. for 250 s to form a textured surface having a pyramid-shapes structure, and then the silicon wafer was washed with deionized water for 80 s.

A first mixed solution and a second mixed solution were prepared with HNO₃ and HF. A concentration of HNO₃ in the first mixed solution was 60 wt %, and a concentration of HF in the first mixed solution was 15 wt %. A concentration of HNO₃ in the second mixed solution was 15 wt %, and a concentration of HF in the second mixed solution was 60 wt %. Then, the silicon wafer having the textured surface was immersed in the first mixed solution for 15 s, and then immersed in the second mixed solution for 5 s, which repeated for 10 times to form the rounded textured surface having a rounded pyramid-shaped structure.

A third mixed solution was prepared with CuCl₂ and HF. In the third mixed solution, a concentration of Cu²⁺ was 3 wt %, and a concentration of HF was 50 wt %. The rounded textured surface was immersed in the third mixed solution for 150 s, so that site-specific induced etching was performed on the rounded textured surface to form pits with copper particles accumulated.

A fourth mixed solution was prepared with HCl and H₂O₂. A concentration of HCl in the fourth mixed solution was 2 wt %, and a concentration of H₂O₂ in the fourth mixed solution was 5 wt %. The rounded textured surface was immersed in the fourth mixed solution for 50 s to remove the accumulated copper particles, forming the pits and finishing the texturing process.

The silicon wafer having a rounded textured surface prepared in the present embodiment was tested, a density of the pits on the rounded textured surface was 50/cm², a width of the pits was 0.05 μm, and a depth of the pits was 25 nm.

The silicon wafer having the rounded textured surface with pits was subjected to processing such as boron diffusion, washing, coating, printing and sintering to prepare a solar cell.

Electrical performance of the solar cell prepared in the present embodiment was shown in Table 1.

### Second Embodiment

Differences between the second embodiment and the first embodiment were shown below. A first mixed solution and a second mixed solution were prepared with HNO₃ and HF. A concentration of HNO₃ in the first mixed solution was 80 wt %, and a concentration of HF in the first mixed solution was 10 wt %. A concentration of HNO₃ in the second mixed solution was 10 wt %, and a concentration of HF in the second mixed solution was 80 wt %. Then, the silicon wafer having the textured surface was immersed in the first mixed solution for 20 s, and then immersed in the second mixed solution for 10 s, which repeated for 15 times to form the rounded textured surface.

The silicon wafer having a rounded textured surface prepared in the present embodiment was tested, a density of the pits on the rounded textured surface was 60/cm², a width of the pits was 0.06 μm, and a depth of the pits was 30 nm.

The silicon wafer having the rounded textured surface with pits was subjected to processing such as boron diffusion, washing, coating, printing and sintering to prepare a solar cell.

Electrical performance of the solar cell prepared in the present embodiment was shown in Table 1.

### Third Embodiment

Differences between the third embodiment and the first embodiment were shown below. A third mixed solution was prepared with CuCl₂ and HF. In the third mixed solution, a concentration of Cu²⁺ was 5 wt %, and a concentration of HF was 60 wt %. The rounded textured surface was immersed in the third mixed solution for 200 s, so that site-specific induced etching was performed on the rounded textured surface to form pits with copper particles accumulated.

The silicon wafer having a rounded textured surface prepared in the present embodiment was tested, a density of the pits on the rounded textured surface was 80/cm², a width of the pits was 0.07 μm, and a depth of the pits was 40 nm.

The silicon wafer having the rounded textured surface with pits was subjected to processing such as boron diffusion, washing, coating, printing and sintering to prepare a solar cell.

Electrical performance of the solar cell prepared in the present embodiment was shown in Table 1.

### First Comparative Embodiment

A precleaning solution was prepared with NaOH and H₂O₂. A concentration of NaOH in the precleaning solution was 0.1 wt %, and a concentration of H₂O₂ in the precleaning solution was 3 wt %. A silicon wafer was treated in the precleaning solution at a temperature of 65° C. for 100 s, and then the silicon wafer was washed with deionized water for 80 s.

An alkaline texturing solution was prepared with NaOH and a texturing additive. In the alkaline texturing solution, a concentration of NaOH was 2 wt %, and a concentration of the texturing additive was 0.5 wt %. The precleaned silicon wafer was treated in the alkaline texturing solution at a temperature of 70° C. for 250 s to form a textured surface having a pyramid-shaped structure, and then the silicon wafer was washed with deionized water for 80 s.

A first mixed solution and a second mixed solution were prepared with HNO₃ and HF. A concentration of HNO₃ in the first mixed solution was 60 wt %, and a concentration of HF in the first mixed solution was 15 wt %. A concentration of HNO₃ in the second mixed solution was 15 wt %, and a concentration of HF in the second mixed solution was 60 wt %. Then, the silicon wafer having the textured surface was immersed in the first mixed solution for 15 s, and then immersed in the second mixed solution for 5 s, which repeated for 10 times to form the rounded textured surface.

The silicon wafer having the rounded textured surface with pits was subjected to processing such as boron diffusion, washing, coating, printing and sintering to prepare a solar cell.

Electrical performance of the solar cell prepared in the present comparative embodiment was shown in Table 1.

### Second Comparative Embodiment

A precleaning solution was prepared with NaOH and H₂O₂. A concentration of NaOH in the precleaning solution was 0.1 wt %, and a concentration of H₂O₂ in the precleaning solution was 3 wt %. A silicon wafer was treated in the precleaning solution at a temperature of 65° C. for 100 s, and then the silicon wafer was washed with deionized water for 80 s.

An alkaline texturing solution was prepared with NaOH and a texturing additive. In the alkaline texturing solution, a concentration of NaOH was 2 wt %, and a concentration of the texturing additive was 0.5 wt %. The precleaned silicon wafer was treated in the alkaline texturing solution at a temperature of 70° C. for 250 s to form a textured surface having a pyramid-shaped structure, and then the silicon wafer was washed with deionized water for 80 s.

The silicon wafer having the rounded textured surface with pits was subjected to processing such as boron diffusion, washing, coating, printing and sintering to prepare a solar cell.

Electrical performance of the solar cell prepared in the present comparative embodiment was shown in Table 1.

### Third Comparative Embodiment

Differences between the third comparative embodiment and the first embodiment were shown below. A mixed solution were prepared with HNO₃ and HF. A concentration of HNO₃ in the mixed solution was 40 wt %, and a concentration of HF in the mixed solution was 40 wt %. Then, the silicon wafer having the textured surface was immersed in the mixed solution for 200 s to form the rounded textured surface.

The silicon wafer having a rounded textured surface prepared in the present comparative embodiment was tested, a density of the pits on the rounded textured surface was 5/cm², a width of the pits was 0.01 μm, and a depth of the pits was 2 nm.

The silicon wafer having the rounded textured surface with pits was subjected to processing such as boron diffusion, washing, coating, printing and sintering to prepare a solar cell.

Electrical performance of the solar cell prepared in the present comparative embodiment was shown in Table 1.

### Fourth Comparative Embodiment

Differences between the fourth comparative embodiment and the first embodiment were shown below. A first mixed solution and a second mixed solution were prepared with HNO₃ and HF. A concentration of HNO₃ in the first mixed solution was 15 wt %, and a concentration of HF in the first mixed solution was 60 wt %. A concentration of HNO₃ in the second mixed solution was 60 wt %, and a concentration of HF in the second mixed solution was 15 wt %.

The silicon wafer having a rounded textured surface prepared in the present comparative embodiment was tested, a density of the pits on the rounded textured surface was 20/cm², a width of the pits was 0.02 μm, and a depth of the pits was 4 nm.

The silicon wafer having the rounded textured surface with pits was subjected to processing such as boron diffusion, washing, coating, printing and sintering to prepare a solar cell.

Electrical performance of the solar cell prepared in the present comparative embodiment was shown in Table 1.

### Fifth Comparative Embodiment

Differences between the fifth comparative embodiment and the first embodiment were shown below. Then, the silicon wafer having the textured surface was immersed in the first mixed solution for 5 s, and then immersed in the second mixed solution for 15 s, which repeated for 10 times to form the rounded textured surface.

The silicon wafer having a rounded textured surface prepared in the present comparative embodiment was tested, a density of the pits on the rounded textured surface was 20/cm², a width of the pits was 0.1 μm, and a depth of the pits was 10 nm.

The silicon wafer having the rounded textured surface with pits was subjected to processing such as boron diffusion, washing, coating, printing and sintering to prepare a solar cell.

Electrical performance of the solar cell prepared in the present comparative embodiment was shown in Table 1.

TABLE 1

| | | | | | Reflectivity of a |
|---|---|---|---|---|---|
| | Uoc(V) | Isc(A) | FF(%) | Eta(%) | textured surface (%) |
| First Embodiment | 0.7196 | 11.619 | 82.75 | 25.24 | 3.29 |
| Second | 0.7201 | 11.621 | 82.88 | 25.35 | 3.16 |
| Embodiment | | | | | |
| Third Embodiment | 0.7198 | 11.620 | 82.79 | 25.29 | 3.25 |
| First Comparative | 0.7193 | 11.530 | 82.56 | 24.98 | 11.2 |
| Embodiment | | | | | |
| Second | 0.714 | 11.540 | 82.70 | 24.86 | 9.5 |
| Comparative | | | | | |
| Embodiment | | | | | |
| Third Comparative | 0.715 | 11.545 | 82.60 | 25.00 | 8.8 |
| Embodiment | | | | | |
| Fourth Comparative | 0.714 | 11.547 | 82.55 | 25.02 | 8.6 |
| Embodiment | | | | | |
| Fifth Comparative | 0.714 | 11.548 | 82.59 | 15.04 | 8.5 |
| Embodiment | | | | | |

In Table 1, Uoc represents the open-circuit voltage; Isc represents the short-circuit current; FF represents the fill factor; and Eta represents the conversion efficiency of the cell.

The data of the first comparative embodiment in Table 1 was compared to the data of the second comparative embodiment shown in Table 1. It can be concluded that since only the pyramid-shaped structure was rounded in the first comparative embodiment, and the passivation performance was increased, and the open-circuit voltage was increased. However, the reflectivity partially lost, which led to decrease of the short-circuit current. Thus, it can be concluded that when the rounding treatment was performed merely on the textured surface, only the passivation performance of the silicon wafer was improved but the reflectivity cannot be lowered, and the conversion efficiency of the solar cell was relatively low.

The data of the first embodiment in Table 1 was compared to the data of the first comparative embodiment shown in Table 1. It can be concluded that since nanometer-scale pits was formed on the rounded textured surface by method of metal etching in the first embodiment, the specific surface area of the rounded textured surface was increased, so that the reflectivity of the rounded textured surface lowered from 11.2% to 3.29%. Therefore, the solar cell prepared in the first embodiment could have high passivation efficiency and low reflectivity performance at the same time. In this way, both the open-circuit voltage and the short-circuit current could be improved, and the conversion efficiency of the solar cell was increased from 24.98% to 25.24%.

The data of the first embodiment in Table 1 was compared to the data of the third comparative embodiment shown in Table 1. It can be concluded that when a rounding treatment is performed on the textured surface for one time with a mixed solution of HF and HNO₃ without limiting the concentration of HF and the concentration of HNO₃, the silicon oxide cannot be generated and removed effectively in the rounding treatment, which leads to poor rounding efficiency and affects the efficiency of forming the pits on the rounded textured surface afterwards. Thus, the reflectivity of the solar cell was increased, but both the short-circuit current and the open-circuit voltage were lowered.

The data of the first embodiment in Table 1 was compared to the data of the fourth comparative embodiment shown in Table 1. It can be concluded that when the concentration of the HNO₃ in the first treatment was lower than the concentration of HF in the first treatment, and the concentration of the HNO₃ in the second treatment was higher than the concentration of HF in the second treatment, the sharp-shaped area cannot be thoroughly removed. Thus, the rounding efficiency was poor, and both the short-circuit current and the open-circuit voltage were lowered.

The data of the first embodiment in Table 1 was compared to the data of the fifth comparative embodiment shown in Table 1. It can be concluded that when the time of the first treatment was shorter than the time of the second treatment, the oxidation efficiency was poor. Thus, the rounding efficiency was poor, and the efficiency of forming pits on the rounded textured surface was poor, and both the open-circuit voltage and the short-circuit current were lowered.

The technical features of the above to mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above to described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

What is claimed is:

1. A method for texturing a silicon wafer, comprising following steps:
forming a textured surface on a silicon wafer, wherein a pyramid-shaped structure is formed on the textured surface;
subjecting a rounding treatment on the pyramid-shaped structure to form a rounded pyramid-shaped structure and obtaining a rounded textured surface, wherein the rounding treatment comprises: a first treatment of first placing the silicon wafer having the textured surface in a first mixed solution; a second treatment of then placing silicon wafer having the textured surface in a second mixed solution; and at least repeating the first treatment and the second treatment twice, wherein the first mixed solution comprises HNO₃ and HF, a mass fraction of HNO₃ in the first mixed solution is greater than a mass fraction of HF in the first mixed solution, the second mixed solution comprises HNO₃ and HF, and a mass fraction of HNO₃ in the second mixed solution is less than a mass fraction of HF in the second mixed solution, and a time of the first treatment is longer than a time of the second treatment; and
forming pits on the rounded textured surface to texture the silicon wafer, wherein a density of the pits on the rounded textured surface is in a range of 10/cm² to 100/cm², a width of one of the pits is in a range of 0.01 μm to 0.08 μm, and a depth of one of the pits is in a range of 5 nm to 50 nm.

2. The method of claim 1, wherein the first treatment and the second treatment repeats 5 times to 20 times.

3. The method of claim 1, wherein the time of the first treatment is in a range of 15 s to 20 s; and/or,
the time of the second treatment is in a range of 5 s to 10 s.

4. The method of claim 1, wherein a concentration of HNO₃ in the first mixed solution is in a range of 40 wt % to 80 wt %, and a concentration of HF in the first mixed solution is in a range of 10 wt % to 20 wt %; and/or,
a concentration of HNO₃ in the second mixed solution is in a range of 10 wt % to 20 wt %, and a concentration of HF in the second mixed solution is in a range of 40 wt % to 80 wt %.

5. The method of claim 1, wherein the step of forming pits on the rounded textured surface comprises forming the pits on the rounded textured surface by method of metal etching.

6. The method of claim 5, wherein the step of forming the pits on the rounded textured surface by method of metal etching comprises:
successively performing a third treatment with a third mixed solution and a fourth treatment with a fourth mixed solution the rounded pyramid-shaped structure,
wherein the third mixed solution comprises cupric ions and HF, a concentration of the cupric ions is in a range of 1 wt % to 5 wt %, a concentration of HF is in a range of 40 wt % to 60 wt %, and a time of the third treatment is in a range of 100 s to 200 s,
the fourth mixed solution comprises HCl and H₂O₂, a concentration of HCl is in a range of 2 wt % to 10 wt %, a concentration of H₂O₂ is in a range of 5 wt % to 20 wt %, and a time of the fourth treatment is in a range of 50 s to 200 s.

7. The method of claim 1, wherein a size of the pyramid-shaped structure is defined as a, and the size a of the pyramid-shaped structure is in a range of 1 μm to 2.5 μm.

8. A textured silicon wafer prepared by the method of claim 1.

9. A method for preparing a crystalline silicon cell, comprising the method of claim 1.

10. A crystalline silicon cell prepared by the method of claim 9.
